(19) United States
(12) Patent Application Publication
(10) Pub. No.: US 2008/0063810 A1
(43) Pub. Date: Mar. 13, 2008

(54) In-situ process state monitoring of chamber

(75) Inventors: Soonam Park, Sunnyvale, CA (US); Qiwei Liang, Fremont, CA (US); Zhong Qiang, Saratoga, CA (US); Dmitry Lubomirsky, Cupertino, CA (US); Young S. Lee, San Jose, CA (US)

Correspondence Address: TOWNSEND AND TOWNSEND AND CREW LLP / AMAT, TWO EMBARCADERO CENTER, EIGHTH FLOOR, SAN FRANCISCO, CA, 94111-3834, US

(73) Assignee: Applied Materials, Inc., Santa Clara, CA (US)

(21) Appl. No.: 11/508,524

(22) Filed: Aug. 23, 2006

(51) Int. Cl. H05H 1/24; C23C 16/00

(52) U.S. Cl. 427/569; 118/715

(57) ABSTRACT

The process state of a chamber after a maintenance procedure can be monitored in-situ in order to ensure that the chamber is ready for processing, while minimizing waste and downtime due to aftereffects of the maintenance procedure. The composition of a bulk plasma in a process chamber can be analyzed using an analytical tool to capture the emission spectrum of the plasma. The spectrum can be analyzed to generate a model of the current chamber conditions, which can be compared to a model of ideal chamber conditions using a statistical analysis approach such as multivariate primary component analysis. If the current and ideal models match to within a set confidence level, the chamber conditions are acceptable for processing devices, and any processing of cycling workpieces or other plasma-cleansing processes can be stopped.

### BACKGROUND OF THE INVENTION

The present invention relates to the processing of a workpiece such as a substrate or silicon wafer. More particularly, the invention relates to a method and apparatus for monitoring the composition of a plasma when an integrated circuit is manufactured using a plasma processing technique.

One of the steps in the fabrication of modern semiconductor devices is the formation of a thin film on a semiconductor substrate through a chemical reaction of selected gases. One such deposition process is referred to as chemical vapor deposition (“CVD”). Conventional thermal CVD processes supply reactive gases to the surface of a substrate, where heat-induced chemical reactions take place to produce a desired film. Plasma-enhanced CVD techniques, on the other hand, promote excitation and/or dissociation of the reactant gases through the application of radio-frequency (“RF”), microwave, or other energy to a reaction zone near the substrate surface, thereby creating a plasma. The high reactivity of the species in the plasma reduces the energy required for a chemical reaction to take place, and thus lowers the temperature required for such CVD processes as compared to conventional thermal CVD processes. These advantages are further exploited by high-density-plasma (“HDP”) CVD techniques, in which a dense plasma is formed at low vacuum pressures so that the plasma species are even more reactive.

A problem with existing processes for manufacturing devices such as semiconductor chips is that certain contaminants can be present in the plasma and get deposited onto the surfaces and into films of these devices during manufacture, which can damage the devices. Since processes such as CVD are used to deposit material components of specific reactive gases, it is desirable to minimize contaminants in the CVD chamber environment as those contaminants can alter the concentrations of the reactive gases used for processing which can negatively impact the function of the devices on the substrate wafer, reducing device yields. In order to minimize the presence of contaminants, device manufacturers typically undertake preventative maintenance (PM) procedures, such as by cleaning the inside of each process chamber after running for a certain period of time or processing a selected number of substrates or workpieces, such as after processing 3,000 wafers in a process chamber.

When cleaning a process chamber, for example, each component having an exposed surface in the interior of the processing chamber can be wiped, sprayed, or otherwise exposed to various cleaning agents or solvents, such as de-ionized water, isopropyl alcohol (IPO), etc. In one particular example, components in the chamber undergo a wet etch in order to remove any contamination. After removing contaminants from these surfaces, however, there will be some level of residual contamination or residue on the surfaces due in part to the cleaning process. It has been demonstrated that wafers processed shortly after a cleaning process exhibit different properties, such as differing layer thicknesses and altered device performance. The gas concentrations of each gaseous species in the bulk plasma have been shown to be sensitive to chamber conditions due to surface-plasma interactions, such as radical recombination and surface reaction rate variation, such that the deposition process, for example, does not deposit a material in an ideal way. It is apparent that something in the chamber has changed as a result of the PM and the chemicals or process used therein.

In order to minimize these differing properties after a PM or other such process, device manufacturers typically run a number of “dummy” workpieces, or cycling workpieces, through the process chamber. As used herein, a testing or cycling workpiece refers to any workpiece, substrate, or material placed into a processing chamber that is not intended to result in a useful product, but is simply used to cycle the process chamber in order to help get the chamber back near the state the chamber was in before the PM or other such process. In one example, a manufacturer processes about 200 cycling workpieces in the process chamber after a PM before processing an actual wafer that will be used to manufacture a device such as a semiconductor device. In this example, about 200 testing silicon wafers are wasted for each 3,000 wafers processed, simply due to the need to remove residue after a cleaning procedure. While the relative expense may be acceptable, as each cycling wafer may be on the order of about $200 compared to around $10K for a patterned wafer involving 100-120 process steps, the cost still is higher than desired as the manufacturer typically runs more cycling wafers through the system than is needed. For example, if it is found that it is necessary to run between 50 and 200 cycling wafers through a chamber after a PM, the manufacturer has no way of knowing how many are needed after a particular PM, so the manufacturer typically will play it safe and run 200 cycling wafers through the system. The extra cost is equal to the cost of only about three patterned wafers, which can be far cheaper than producing several patterned wafers that do not perform as expected. Still, it would be desirable to save the $30K after each PM, as well as reduce the downtime needed to run the extra, unnecessary cycling wafers. To run 200 cycling wafers can take about two days in one example. This system downtime further increases the cost per chip and reduces throughput.

It therefore is desirable to develop a way to determine the necessary number of cycling wafers or other substrates to cycle after a preventative maintenance or other procedure before processing actual workpieces to produce the intended devices.

It also is desirable to develop a method for monitoring the relative composition of the plasma during processing so that processing can be stopped if the relative composition changes or otherwise exceeds a set confidence level or composition variance threshold.

### SUMMARY OF THE INVENTION

Systems and methods in accordance with various embodiments of the present invention provide for in-process determination of chamber conditions during the processing of a substrate or other workpiece. Such determinations are not only advantageous during processing of a batch of wafers, to ensure that process chamber conditions are sufficiently near ideal conditions, but can be particularly advantageous after maintenance procedures on a chamber, such as by performing a wet etch on the chamber interior. Because the chamber conditions can be affected by the maintenance procedures as discussed elsewhere herein, it can be desirable to determine when the process chamber conditions are back to near ideal operating conditions within a set confidence level or within a desired threshold.

In one embodiment, a testing workpiece is placed in a process chamber, wherein a plasma is generated in order to process the wafer. Although the cycling workpiece likely will not actually be manufactured into a working and sellable product, the processing of the cycling workpiece in the process chamber should use similar procedures and materials to an actual workpiece to be processed in order to accurately determine process conditions. During the processing of the cycling workpiece, radiation emitted by the plasma can be measured, such as by using an analytical tool such as an optical emission spectrograph (OES). A set of spectral and/or composition data for the current process then can be generated.

Once the spectral and/or composition data is generated, a current model of chamber conditions can be determined using that data. The current model can be compared with an ideal model of chamber conditions, such as by using a statistical comparison technique like multivariate primary component analysis. For the comparison, each of the condition models is quantified and compared to determine whether the current and ideal models match to within a selected confidence level. If the models match within this confidence level, the processing of cycling workpieces can be stopped, and processing of actual workpieces to create working devices can be started using the current chamber conditions.

If the models do not match within this confidence level, the processing of cycling workpieces can continue until the models match within the confidence level. For the subsequent cycling wafers, the chamber conditions can be examined and analyzed for each cycling wafer, or at any random, regular, or other appropriate interval.

These and other embodiments of the present invention, as well as its advantages and features, are described in more detail in conjunction with the text below and attached figures.

### BRIEF DESCRIPTION OF THE DRAWINGS

Various embodiments in accordance with the present invention will be described with reference to the drawings, in which:

FIG. 1 illustrates a portion of a CVD processing chamber of the prior art;

FIG. 2 illustrates a portion of a CVD processing chamber and monitoring system in accordance with one embodiment of the present invention;

FIG. 3 illustrates (a) a spectral analysis of the components of a plasma used for processing and (b) a plot of plasma component status per wafer processed after a PM process in accordance with one embodiment of the present invention;

FIG. 4 illustrates steps of a method for monitoring plasma component content in accordance with one embodiment of the present invention;

FIG. 5 is a simplified diagram of a high-density plasma chemical vapor deposition system that can be used in accordance with one embodiment of the present invention; and

FIG. 6 is a flow chart of an exemplary process control computer program product that can be used to control the exemplary deposition system of FIG. 5 in accordance with one embodiment of the present invention.

### DETAILED DESCRIPTION OF THE EMBODIMENTS

Systems and methods in accordance with various embodiments of the present invention can overcome the aforementioned and other deficiencies in existing processing systems by providing for in-situ process state monitoring for chamber conditions, such as a determination of plasma composition during processing, as well as after a process such as a preventative maintenance (PM) or other such process. In order to properly monitor the chamber conditions, an ideal model is created that matches ideal chamber conditions for the process. Through a calibration procedure, for example, it can be determined which values of each material component of a bulk plasma in the process chamber produce the best resulting material and/or device. These material components can include, for example, the reactive gases used for a deposition. This model then can be quantified for comparison as will be discussed later herein. For subsequent processing, a current model can be generated for the current chamber conditions by analyzing the plasma emission spectrum, for example, then comparing the current model to the ideal model using a statistical comparison technique such as multivariate principal component analysis.

In one embodiment, a high density plasma chemical vapor deposition (HDP-CVD) process chamber is cleaned with a wet etch process as known in the art. After the cleaning process, the optical emission of a plasma in a chemical vapor deposition (CVD) process is examined during a deposition on at least one of a number of cycling workpieces after a PM in order to determine the relative composition of the plasma, particularly the relative concentration corresponding to selected material components in the plasma. A principal component analysis or other statistical analysis is done on the optical spectrum of the plasma, in order to determine how closly the composition of the plasma matches a previous, ideal, set, or other appropriate plasma composition, such as may correspond to the ideal model discussed above. A minimum confidence level can be set such that when the plasma is near the ideal plasma composition within the set confidence level, processing of cycling workpieces can be stopped and the processing chamber can return to processing actual workpieces used to manufacture devices such as semiconductor devices. In one embodiment, appropriate confidence values are in the range of about 90% to about 95%, or can be at least about 90% in another embodiment.

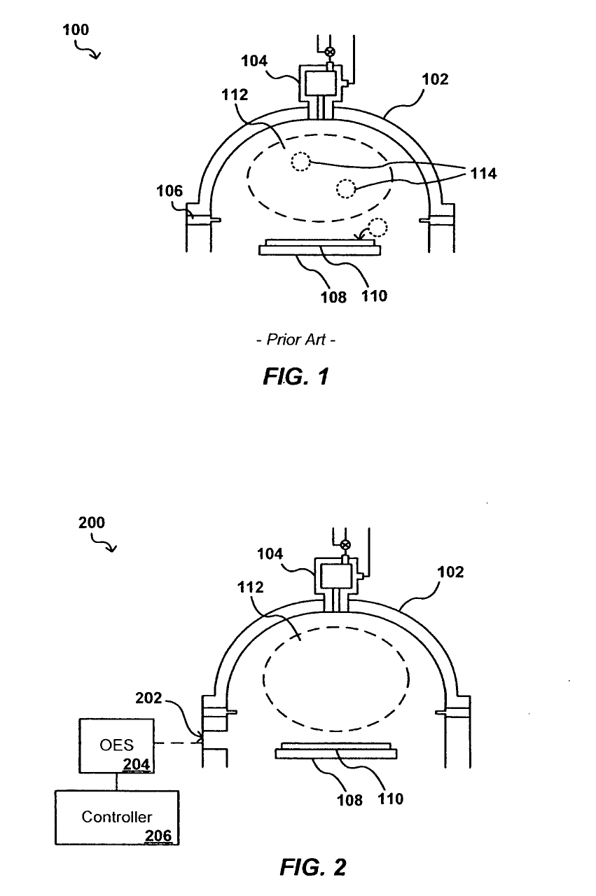

For example, FIG. 1 illustrates a cross-section of a portion of an exemplary plasma processing chamber 100 useful for depositing a film on, or etching material from, a substrate 110, such as a silicon wafer. The substrate is placed on a substrate support 108 in the chamber, which in this example is enclosed by a dome 102 and includes components such as a gas ring 106 and gas inlet port 104 allowing reactive gases to be flowed into the chamber to form a plasma 112 over the substrate 110 as discussed elsewhere herein and known in the art. The heating of the chamber, the application of energy, and the reactions with the plasma gases can cause particles of the chamber components to pass into the plasma, particularly as the chamber ages. Further, contaminants from the gases, substrates, and other components can build up in the chamber over time. In order to prevent these contaminants from building up in the plasma 112 to an unacceptable level that negatively impacts device performance, as well as altering the relevant concentration of the process gases in the plasma, the chamber is periodically cleaned as discussed above using a chemical or solvent such as de-ionized water or isopropyl alcohol (IPO). Methods for cleaning process chambers, such as wet etch processes, are well known in the art and will not be discussed herein in detail.

After the chamber is cleaned, seasoned, coated, and/or otherwise processed during the PM or other such process, a series of cycling workpieces is run through the chamber and processed using the plasma in order to ensure that any residue or contamination 114 as a result of the PM process is transferred to the cycling workpieces, or otherwise expelled from the chamber during the processing of the cycling workpieces, so that the plasma is near the ideal composition within a set confidence level when an actual workpiece to be processed is again placed in the chamber for processing.

As shown in the example of FIG. 2, a processing chamber 200 often includes at least one window 202 allowing an operator or other person or device to see into the chamber 200. Reference numbers are carried over between figures where appropriate for simplicity, but should not be read as a limitation on the various embodiments. A system in accordance with one embodiment takes advantage of such a window by positioning an analytical tool such as an optical emission spectrograph(OES) relative to the window such that the analytical tool can analyze the spectrum of the plasma. For example, an OES 204 is shown positioned relative to the chamber window 202 such that the OES can capture an optical emission of the plasma 112 during deposition processes. A spectral analysis of the emission can be performed as necessary, such as for every cycling workpiece, at regular intervals, random intervals, or at any other appropriate interval or timing. The generated spectrum, spectrum data, and/or spectral analysis can be passed to a controller 206, which can be any appropriate device such as an automated controller in a closed loop system or a stand-alone computer or display being monitored by an employee as would be apparent to one of ordinary skill in the art. The controller can generate a model of the current plasma conditions, and can perform a primary component analysis on the spectrum data to compare the current plasma composition status to the ideal plasma composition status. The controller then can indicate to a user of the system, or to an automated process control, whether the plasma composition is sufficiently near the ideal composition, within the confidence level, such that cycling workpiece processing can stop. The controller also can communicate other appropriate information as would be apparent to one of ordinary skill in the art, such as primary component levels, confidence levels, statistical data, plots, etc.

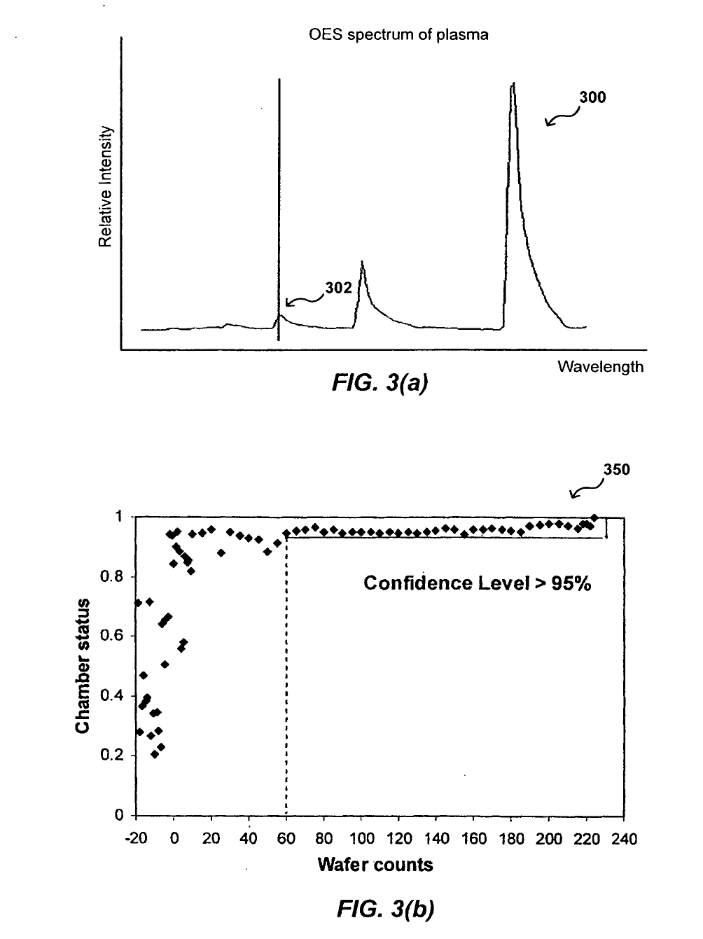

FIG. 3(a) illustrates an exemplary emission spectrum 300 for a plasma as detected by an OES device or other such spectral analyzer. It should be noted that this spectrum is included for explanation purposes, and should not be interpreted as a limitation on any of the present embodiments. This spectrum is shown as a plot of relative intensity versus wavelength. Since the wavelength of a peak 302 corresponding to a material component of the plasma is known, analyzing such a plot can provide for the determination of the relative concentration of each such material component. For example, the spectral data for FIG. 3(a) can be passed to a controller or other processing device as discussed above. The controller can analyze the spectrum and perform a principal component analysis (PCA), correspondence analysis, confirmatory factor analysis, or another statistical or mathematical analysis on the spectrum data to compare the data to an ideal set of data.

A method in accordance with one embodiment utilizes multivariate PCA to reduce the dimensionality of the spectral data while retaining as much information as possible. The principal components can be a combination of variables demonstrating the largest amount of variation, with the second principal component defining next largest amount of variation (independent of the first principal component), and so on. There can be as many principal components as there are material components of the plasma. There are several algorithms for calculating the principal components as known in the art, which will produce the same results where the variations are determinate. Instead of comparing each material component individually, PCA allows the system to compare a single value for the plasma composition status to that of a prior or set composition status, to determine whether the plasma is at a desired composition within a set confidence level.

In one exemplary approach, all plasma component information before a PM procedure is collected via PCA, and then used as “golden” chamber status data, or optimal chamber data. As cycling workpieces are run through processing after the PM procedure, the plasma components are monitored and compared to the gold chamber status data in-situ. Once the plasma components are near the corresponding gold chamber status data values within a predetermined confidence level, cycling of the cycling workpieces wafer process will stop and then the actual production run can begin.

In the case of workpiece processing after a wet etch or other such process, the plasma chemistry is analyzed to determine when the plasma is sufficiently near the ideal composition. In order to make a quick and accurate determination, the plasma chemistry first can be quantified. For example, the ideal material component levels can be set to a value such as 1, or 100%, of the desired amount. After quantifying the material component levels, a statistical analysis of the captured spectral data can be done to compare the current values with the ideal values and determine when the overall plasma component level is sufficiently near 1 (or another set quantity for the overall plasma status). A PCA process can use the “golden” chamber conditions, or other appropriate chamber data, as a reference, and can compare all other chamber conditions to that reference. If the chamber conditions match perfectly with the golden chamber data, the quantifying PCA process can produce a value of 1 (or another appropriate value, depending upon the quantifying process). An appropriate statistical analysis can indicate when the plasma chemistry after the wet etch sufficiently matches the plasma chemistry before the wet etch, within a given confidence level as set by the client or customer. The confidence level can be determined using standard statistical analytical approaches. When the chamber status match is reached within the desired confidence level, the processing of cycling workpieces can be stopped and the chamber can be returned to on-line status and used to process subsequent workpieces to manufacture devices. FIG. 3(b) illustrates an exemplary plot 350 of chamber status (as determined by PCA) versus the number of wafers processed in the chamber after a PM. As can be seen, the plasma component analysis for about the first 40 cycling workpieces after a PM indicates that the plasma chemistry is very unpredictable. For about the next 40 cycling wafers, the plasma composition is near the desired levels, but still is outside the set confidence level (here a confidence level of at least 95% as selected by an operator or process engineer, for example). After processing about 80 wafers, the composition of the plasma is at about the desired composition, and within the set confidence level, so that after processing about 80 cycling workpieces in this example, the processing of cycling workpieces can be stopped and processing of actual workpieces can be started. If the system had been set to process 200 wafers by default, as discussed above, the system would have wasted about 120 workpieces, and would have lost over a day in processing time.

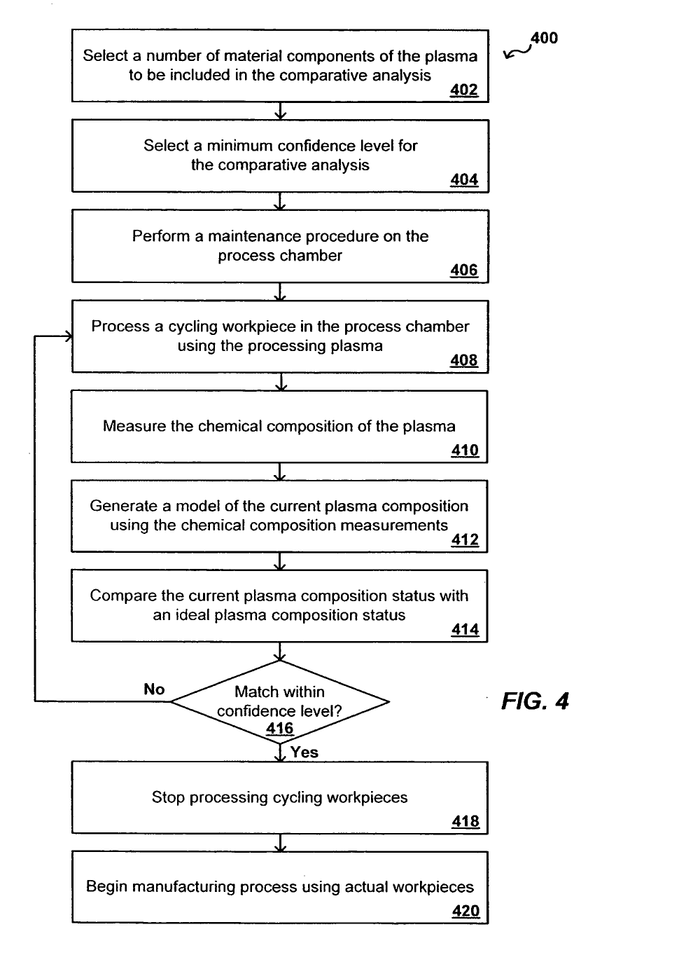

FIG. 4 illustrates steps of an exemplary method 400 for monitoring plasma composition status after a maintenance or other such process in accordance with one embodiment. In such a method, a number of material components to be included in the analysis can be selected to quantify the plasma composition 402, which can include all of the materials intended to be injected into the chamber for processing, or a subset of materials which most affect the processing. A minimum confidence level also is selected for the plasma composition status 404, which corresponds to a maximum statistical uncertainty, or minimum statistical certainty, that is allowed for the comparative plasma composition while processing a workpiece.

A maintenance procedure is performed on the process chamber 406, such as a PM wet etch or other cleaning, seasoning, coating, or other treating process. A cycling workpiece (or workpiece not actually intended to result in a manufactured device or other final product) is placed into the chamber and processed using a plasma created from the injected reactive gases 408. During the processing of the cycling workpiece, the chemical composition of the plasma can be examined using an analytical tool 410. For such in-situ measurements in one example, radiation emitted from a window port of the processing chamber as a result of the plasma is captured by a spectral analysis tool such as OES, which can measure the emission from the plasma during a process such as a deposition or etch and generate spectral data. The spectrum or spectral values can be sent to a computer including software for analyzing the spectral values at or near particular wavelengths. A model of the current plasma composition status is generated 412 based on the spectrum data. The current plasma composition status then can be compared to an ideal plasma composition 414, such as by using multivariate PCA. If the current and ideal plasma composition status match to within the set confidence level 416, then the processing of cycling workpieces can be stopped 418 and processing of actual workpieces can begin 420. If the current and ideal plasma composition status do not match to within the set confidence level, then another cycling wafer can be processed in the chamber until the statuses match to within the desired confidence level.

Such monitoring also can be used at other times during processing. For example, the monitoring of spectral emissions from the plasma can be done during processing of actual workpieces, such as the deposition of a thin film layer onto a semiconductor wafer to create a semiconductor device. A plasma composition status can be determined at any appropriate interval, such as for every wafer, every 10 wafers, at random intervals, increasing frequency with process time, or any other appropriate interval. If at any time the plasma composition status does not match a previous (or set) composition status to within the set confidence level, the processing of wafers can be stopped and a cleaning, coating, or other contaminant reducing or material component level-ensuring process can be executed in order to bring the status quantifications back to within the desired confidence level.

Such a system can be an open loop system or a closed loop system as would be apparent to one of ordinary skill in the art. For example, in an open loop system a controller determining that the chamber status quantification is outside the necessary confidence level can cause a warning signal or message to be displayed or otherwise communicated to an operator, such as by a visual or auditory signal, or via a page or text message. The operator then can manually take the processing chamber offline and conduct a cleaning or other such process as discussed elsewhere herein. In a closed loop system, the controller can automatically take the chamber offline when the confidence level is outside the set confidence level. If multiple processing chambers are being used for the same process step, the controller can indicate that the workpieces being processed to manufacture devices should be re-routed to other online process chambers. Other open and closed-loop steps can be accomplished based on the status and confidence data as would be apparent to one of ordinary skill in the art.

It also should be noted that any other appropriate measurement techniques than OES can be used to measure the plasma chemistry. These include, for example, other emission and absorption spectroscopy devices as known in the art. The spectral data can be analyzed using any appropriate statistical or mathematical analysis technique, and can use any appropriate confidence level or other threshold to determine when the plasma composition is near an ideal, set, previous, or other plasma composition.

Exemplary Substrate Processing System

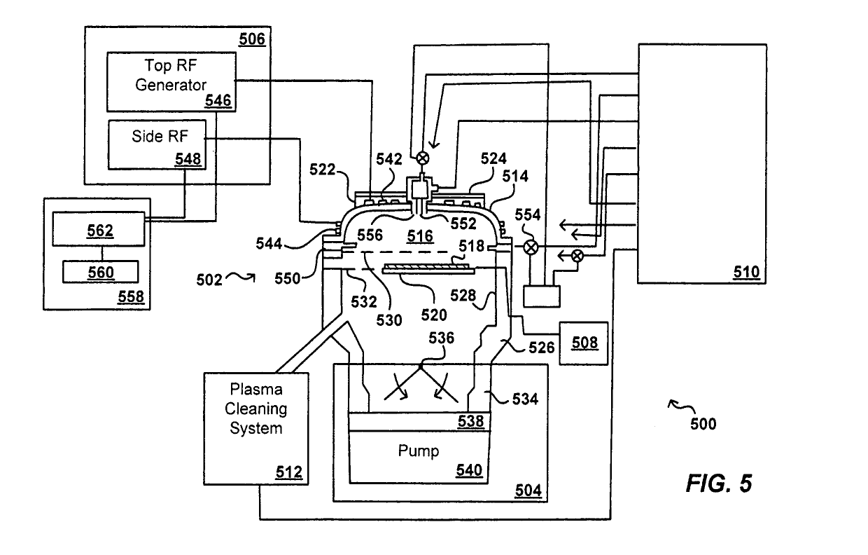

FIG. 5 illustrates an example of a high density plasma chemical vapor deposition (HDP-CVD) system 500 in which a layer can be deposited and a contaminant concentration monitored in accordance with one embodiment. The system 500 includes a chamber 502, a vacuum system 504, a source plasma system 506, a bias plasma system 508, a gas delivery system 510, and a remote plasma cleaning system 512.

The upper portion of the chamber 502 includes a dome 514, which is made of a ceramic dielectric material, such as aluminum oxide or aluminum nitride. The dome 514 defines an upper boundary of a plasma processing region 516. The plasma processing region 516 is bounded on the bottom by the upper surface of a substrate 518 and a substrate support 520.

A heater plate 522 and a cold plate 524 surmount, and are thermally coupled to, the dome 514. The heater plate 522 and cold plate 524 allow control of the dome temperature to within about ±10° C. over a range of about 100° C. to 200° C. This allows optimizing the dome temperature for the various processes. For example, it may be desirable to maintain the dome at a higher temperature for cleaning or etching processes than for deposition processes. Accurate control of the dome temperature also reduces the flake or particle counts in the chamber and improves adhesion between the deposited layer and the substrate.

The lower portion of chamber 502 includes a body 526, which joins the chamber to the vacuum system. A base portion 528 of substrate support 520 is mounted on, and forms a continuous inner surface with, body member 526. Substrates are transferred into and out of the chamber 502 by a robot blade (not shown) through an insertion/removal opening (not shown) in the side of the chamber 502. Lift pins (not shown) are raised and then lowered under the control of a motor (also not shown) to move the substrate from the robot blade at an upper loading position 530 to a lower processing position 532 in which the substrate is placed on a receiving portion of the substrate support 520. The substrate receiving portion can include an electrostatic chuck that secures the substrate to the substrate support 520 during substrate processing. In one embodiment, the substrate support 520 is made from an aluminum oxide or aluminum ceramic material.

The vacuum system 504 includes a throttle body 534, which houses a twin-blade throttle valve 536 and is attached to a gate valve 538 and a turbo-molecular pump 540. It should be noted that the throttle body 534 offers minimum obstruction to gas flow, and allows symmetric pumping. A gate valve 538 can isolate the pump 540 from the throttle body 534, and can also control chamber pressure by restricting the exhaust flow capacity when the throttle valve 536 is fully open. The arrangement of the throttle valve, gate valve, and turbo-molecular pump allow accurate and stable control of chamber pressures from between about 1 milliTorr to about 2 Torr.

The source plasma system 506 includes a top coil 542 and side coil 544, mounted on the dome 514. A symmetrical ground shield (not shown) reduces electrical coupling between the coils. The top coil 542 is powered by top source RF (SRF) generator 546, whereas the side coil 544 is powered by a side SRF generator 548, allowing independent power levels and frequencies of operation for each coil. This dual coil system allows control of the radial ion density in the chamber 502, thereby improving plasma uniformity. The side coil 544 and top coil 542 are typically inductively driven, which does not require a complimentary electrode. In a specific embodiment, the top source RF generator 546 provides up to 2,500 watts of RF power at nominally 2 MHz and the side source RF generator 548 provides up to 5,000 watts of RF power at nominally 2 MHz. The operating frequencies of the top and side RF generators may be offset from the nominal operating frequency (e.g. to 1.7-1.9 MHz and 1.9-2.1 MHz, respectively) to improve plasma-generation efficiency.

A bias plasma system 508 includes a bias RF (“BRF”) generator and a bias matching network. The bias plasma system 508 capacitively couples the substrate 518 to the body 526, which act as complimentary electrodes. The bias plasma system 508 serves to enhance the transport of plasma species (e.g., ions) created by the source plasma system 506 to the surface of the substrate. In a specific embodiment, bias RF generator provides up to 5,000 watts of RF power at 13.56 MHz.

The top and side RF generators 546 and 548 include digitally controlled synthesizers and operate over a frequency range between about 1.8 to about 2.1 MHz. Each generator includes an RF control circuit (not shown) that measures reflected power from the chamber and coil back to the generator and adjusts the frequency of operation to obtain the lowest reflected power, as understood by a person of ordinary skill in the art. RF generators are typically designed to operate into a load with a characteristic impedance of 50 ohms. RF power may be reflected from loads that have a different characteristic impedance than the generator. This can reduce power transferred to the load. Additionally, power reflected from the load back to the generator may overload and damage the generator. Because the impedance of a plasma may range from less than 5 ohms to over 900 ohms, depending on the plasma ion density, among other factors, and because reflected power may be a function of frequency, adjusting the generator frequency according to the reflected power increases the power transferred from the RF generator to the plasma and protects the generator. Another way to reduce reflected power and improve efficiency is with a matching network.

Matching networks match the output impedance of the RF generators 546, 548 with their respective coils 542, 544. The RF control circuit may tune both matching networks by changing the value of capacitors within the matching networks to match the generator to the load as the load changes. The RF control circuit may tune a matching network when the power reflected from the load back to the generator exceeds a certain limit. One way to provide a constant match, and effectively disable the RF control circuit from tuning the matching network, is to set the reflected power limit above any expected value of reflected power. This may help stabilize a plasma under some conditions by holding the matching network constant at its most recent condition.

Other measures may also help stabilize a plasma. For example, the RF control circuit can be used to determine the power delivered to the load (plasma) and may increase or decrease the generator output power to keep the delivered power substantially constant during deposition of a layer.

A gas delivery system 510 provides gases from several sources into the chamber for processing the substrate via gas delivery lines (only some of which are shown). As would be understood by a person of skill in the art, the actual sources used and the actual connection of delivery lines to the chamber 502 varies depending on the deposition and cleaning processes executed within chamber 502. Gases are introduced into the chamber 502 through a gas ring 550 and/or a top nozzle 552.

In one embodiment, first and second gas sources and first and second gas flow controllers provide gas to a ring plenum in gas ring 550 via gas delivery lines (only some of which are shown). The gas ring 550 has a plurality of source gas nozzles that provide a uniform flow of gas over the substrate. Nozzle length and nozzle angle may be changed to allow tailoring of the uniformity profile and gas utilization efficiency for a particular process within an individual chamber. In one embodiment, the gas ring 550 has twelve source gas nozzles made from an aluminum oxide ceramic.

The gas ring 550 also has a plurality of oxidizer gas nozzles that in one embodiment are co-planar with and shorter than source gas nozzles. In some embodiments it is desirable not to mix source gases and oxidizer gases before injecting the gases into the chamber 502. In other embodiments, oxidizer gas and source gas may be mixed prior to injecting the gases into the chamber 502.

In embodiments where flammable, toxic, or corrosive gases are used, it may be desirable to eliminate gas remaining in the gas delivery lines after a deposition. This may be accomplished using a 3-way valve, such as valve 554, to isolate the chamber 502 from the delivery lines and to vent the delivery lines to a vacuum foreline, for example. Other similar valves may be incorporated on other gas delivery lines. Such 3-way valves may be placed as close to the chamber 502 as practical, to minimize the volume of the un-vented gas delivery line (between the 3-way valve and the chamber). Additionally, two-way (on-off) valves (not shown) may be placed between a mass flow controller (“MFC”) and the chamber or between a gas source and an MFC.

The chamber 502 also has a top nozzle 552 and a top vent 556. The top nozzle 552 and top vent 556 allow independent control of top and side flows of the gases, which improves film uniformity and allows fine adjustment of the film's deposition and doping parameters. The top vent 556 is an annular opening around top nozzle 552. In one embodiment, a first gas source supplies source gas nozzles and the top nozzle. The gases supplied to the top nozzle 552 and top vent 556 may be kept separate prior to flowing the gases into the chamber 502, or the gases may be mixed in a top plenum before they flow into the chamber 502. Separate sources of the same gas may be used to supply various portions of the chamber.

A remote microwave-generated plasma cleaning system 512 is provided to periodically clean deposition residues from chamber components. The cleaning system includes a remote microwave generator that creates a plasma from a cleaning gas source (e.g., molecular fluorine, nitrogen trifluoride, other fluorocarbons or equivalents) in a reactor cavity. The reactive species resulting from this plasma are conveyed to the chamber 502 through a cleaning gas feed port via an applicator tube. The materials used to contain the cleaning plasma (e.g., the cavity and applicator tube) are be resistant to attack by the plasma. The distance between the reactor cavity and feed port should be kept as short as practical, since the concentration of desirable plasma species may decline with distance from the reactor cavity. Generating the cleaning plasma in a remote cavity allows the use of an efficient microwave generator and does not subject chamber components to the temperature, radiation, or bombardment of the glow discharge that may be present in a plasma formed in situ. Consequently, relatively sensitive components, such as an electrostatic chuck, do not need to be covered with a cycling wafer or otherwise protected, as may be required with an in situ plasma cleaning process.

A system controller 558 controls the operation of the system 500. In one embodiment, the controller 558 includes a memory 560, such as a hard disk drive, a floppy disk drive (not shown), a card rack (not shown), or other kinds of memory, such as ROM, PROM, and others, coupled to a processor 562. The card rack may contain a single-board computer (SBC) (not shown), analog and digital input/output boards (not shown), interface boards (not shown), and stepper motor controller boards (not shown). The system controller conforms to the Versa Modular European (“VME”) standard, which defines board, card cage, and connector dimensions and types. The VME standard also defines the bus structure as having a 16-bit data bus and 24-bit address bus. The system controller 558 operates under the control of a computer program stored on the hard disk drive or through other computer programs, such as programs stored on a removable disk. The computer program dictates, for example, the timing, mixture of gases, RF power levels and other parameters of a particular process. The interface between a user and the system controller is via a monitor, such as a cathode ray tube (“CRT”) and a light pen.

The system controller 558 operates under the control of a computer program stored in a computer-readable format within the memory 560. The computer program dictates the timing, temperatures, gas flows, RF power levels and other parameters of a particular process. The computer program code can be written in any conventional computer-readable programming language such as 68000 assembly language, C, C++, or Pascal. Suitable program code is entered into a single file, or multiple files, using a conventional text editor and is stored or embodied in a computer-usable medium, such as a memory system of the computer. If the entered code text is in a high level language, the code is compiled, and the resultant compiler code is then linked with an object code of precompiled windows library routines. To execute the linked compiled object code, the system user invokes the object code causing the computer system to load the code in memory. The CPU reads the code from memory and executes the code to perform the tasks identified in the program.

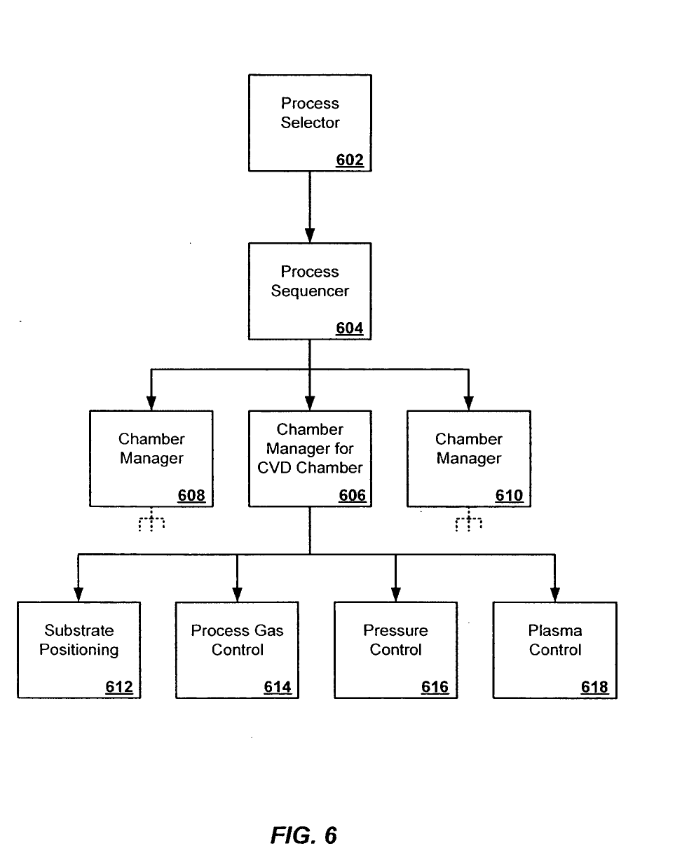

FIG. 6 shows an illustrative block diagram of the hierarchical control structure of computer program 600. A user enters a process set number and process chamber number into a process selector subroutine 602 in response to menus or screens displayed on the CRT monitor by using the light pen interface. The process sets are predetermined sets of process parameters necessary to carry out specified processes, and are identified by predefined set numbers. Process selector subroutine 602 identifies (i) the desired process chamber in a multi-chamber system, and (ii) the desired set of process parameters needed to operate the process chamber for performing the desired process. The process parameters for performing a specific process relate to conditions such as process gas composition and flow rates, temperature, pressure, plasma conditions such as RF power levels, and chamber dome temperature, and are provided to the user in the form of a recipe. The parameters specified by the recipe are entered utilizing the light pen/CRT monitor interface.

The signals for monitoring the process are provided by the analog and digital input boards of the system controller, and the signals for controlling the process are output on the analog and digital output boards of the system controller.

A process sequencer subroutine 604 comprises program code for accepting the identified process chamber and set of process parameters from the process selector subroutine 602 and for controlling operation of the various process chambers. Multiple users can enter process set numbers and process chamber numbers, or a single user can enter multiple process set numbers and process chamber numbers; sequencer subroutine 604 schedules the selected processes in the desired sequence. In one embodiment, sequencer subroutine 604 includes a program code to perform the steps of (i) monitoring the operation of the process chambers to determine if the chambers are being used, (ii) determining what processes are being carried out in the chambers being used, and (iii) executing the desired process based on availability of a process chamber and type of process to be carried out. Conventional methods of monitoring the process chambers can be used, such as polling. When scheduling which process is to be executed, the sequencer subroutine 604 can be designed to take into consideration the “age” of each particular user-entered request, or the present condition of the process chamber being used in comparison with the desired process conditions for a selected process, or any other relevant factor a system programmer desires to include for determining scheduling priorities.

After the sequencer subroutine 604 determines which process chamber and process set combination is going to be executed next, the sequencer subroutine 604 initiates execution of the process set by passing the particular process set parameters to a chamber manager subroutine 606, 608, 610, which controls multiple processing tasks in the chamber and possibly other chambers (not shown) according to the process set sent by sequencer subroutine 604.

Examples of chamber component subroutines are substrate positioning subroutine 612, process gas control subroutine 614, pressure control subroutine 616, and plasma control subroutine 618. Those having ordinary skill in the art will recognize that other chamber control subroutines can be included depending on what processes are selected to be performed in the chamber. In operation, the chamber manager subroutine 606 selectively schedules or calls the process component subroutines in accordance with the particular process set being executed. The chamber manager subroutine 606 schedules process component subroutines in the same manner that the sequencer subroutine 604 schedules the process chamber and process set to execute. Typically, the chamber manager subroutine 606 includes steps of monitoring the various chamber components, determining which components need to be operated based on the process parameters for the process set to be executed, and causing execution of a chamber component subroutine responsive to the monitoring and determining steps.

An exemplary substrate positioning subroutine 612 comprises program code for controlling chamber components that are used to load a substrate onto the substrate support. The substrate positioning subroutine 612 may also control transfer of a substrate into the chamber from, e.g., a plasma-enhanced CVD (“PECVD”) reactor or other reactor in the multi-chamber system, after other processing has been completed.

An exemplary process gas control subroutine 614 has program code for controlling process gas composition and flow rates. The subroutine controls the open/close position of the safety shut-off valves and also ramps up/ramps down the mass flow controllers to obtain the desired gas flow rates. All chamber component subroutines, including the process gas control subroutine 614, are invoked by the chamber manager subroutine 606. The subroutine 614 receives process parameters from the chamber manager subroutine related to the desired gas flow rates.

Typically, the process gas control subroutine 614 opens the gas supply lines, and repeatedly (i) reads the necessary mass flow controllers, (ii) compares the readings to the desired flow rates received from the chamber manager subroutine 606, and (iii) adjusts the flow rates of the gas supply lines as necessary. Furthermore, the process gas control subroutine 614 may include steps for monitoring the gas flow rates for unsafe rates and for activating the safety shut-off valves when an unsafe condition is detected.

In some processes, an inert gas, such as argon, is flowed into the chamber to stabilize the pressure in the chamber before reactive process gases are introduced. For these processes, the process gas control subroutine 614 is programmed to include steps for flowing the inert gas into the chamber for an amount of time necessary to stabilize the pressure in the chamber. The steps described above may then be carried out.

Additionally, when a process gas is to be vaporized from a liquid precursor, for example, tetraethylorthosilane (TEOS), the process gas control subroutine 614 may include steps for bubbling a delivery gas such as helium through the liquid precursor in a bubbler assembly or for introducing the helium to a liquid injection valve. For this type of process, the process gas control subroutine 614 regulates the flow of the delivery gas, the pressure in the bubbler, and the bubbler temperature to obtain the desired process gas flow rates. As discussed above, the desired process gas flow rates are transferred to the process gas control subroutine as process parameters.

Furthermore, the process gas control subroutine 614 includes steps for obtaining the necessary delivery gas flow rate, bubbler pressure, and bubbler temperature for the desired process gas flow rate by accessing a stored table containing the necessary values for a given process gas flow rate. Once the necessary values are obtained, the delivery gas flow rate, bubbler pressure and bubbler temperature are monitored, compared to the necessary values and adjusted accordingly.

The process gas control subroutine 614 may also control the flow of heat-transfer gas, such as helium (He), through the inner and outer passages in the wafer chuck with an independent helium control (IHC) subroutine (not shown). The gas flow thermally couples the substrate to the chuck. In a typical process, the wafer is heated by the plasma and the chemical reactions that form the layer, and the He cools the substrate through the chuck, which may be water-cooled. This keeps the substrate below a temperature that may damage preexisting features on the substrate.

An exemplary pressure control subroutine 616 includes program code for controlling the pressure in the chamber by regulating the size of the opening of throttle valve in the exhaust portion of the chamber. There are at least two basic methods of controlling the chamber with the throttle valve. The first method relies on characterizing the chamber pressure as it relates to, among other things, the total process gas flow, the size of the process chamber, and the pumping capacity. The first method sets the throttle valve to a fixed position. Setting the throttle valve to a fixed position may eventually result in a steady-state pressure.

Alternatively, the chamber pressure may be measured, with a manometer for example, and the position of the throttle valve may be adjusted according to the pressure control subroutine 616, assuming the control point is within the boundaries set by gas flows and exhaust capacity. The former method may result in quicker chamber pressure changes, as the measurements, comparisons, and calculations associated with the latter method are not invoked. The former method may be desirable where precise control of the chamber pressure is not required, whereas the latter method may be desirable where an accurate, repeatable, and stable pressure is desired, such as during the deposition of a layer.

When the pressure control subroutine 616 is invoked, the desired, or target, pressure control subroutine 616 measures the pressure in the chamber by reading one or more conventional pressure manometers connected to the chamber; compares the measured value(s) to the target pressure; obtains proportional, integral, and differential (PID) values from a stored pressure table corresponding to the target pressure, and adjusts the throttle valve according to the PID values obtained from the pressure table. Alternatively, the pressure control subroutine may open or close the throttle valve to a particular opening size to regulate the pressure in the chamber to a desired pressure or pressure range.

An exemplary plasma control subroutine 618 comprises program code for controlling the frequency and power output setting of the RF generators and for tuning the matching networks. The plasma control subroutine 618, like the previously described chamber component subroutines, is invoked by the chamber manager subroutine.

An example of a system that may incorporate some or all of the subsystems and routines described above would be the ULTIMA™ system, manufactured by APPLIED MATERIALS, INC., of Santa Clara, Calif., configured to practice the present invention. Further details of such a system are disclosed in co-pending, commonly assigned U.S. patent application Ser. No. 08/679,927, filed Jul. 15, 1996, entitled “Symmetric Tunable Inductively-Coupled HDP-CVD Reactor,” having Fred C. Redeker, Farhad Moghadam, Hirogi Hanawa, Tetsuya Ishikawa, Dan Maydan, Shijian Li, Brian Lue, Robert Steger, Yaxin Wang, Manus Wong and Ashok Sinha listed as co-inventors, the disclosure of which is incorporated herein by reference. The described system is for explanation purposes only. It would be a matter of routine skill for a person of skill in the art to select an appropriate conventional substrate processing system and computer control system to implement the present invention.

After reading the above description, other recipes that use center-fast deposition will occur to those of ordinary skill in the art. Other variations will also be apparent without departing from the spirit of the invention. These equivalents and alternatives are intended to be included within the scope of the present invention. Therefore, the scope of this invention should not be limited to the embodiments described, but should instead be defined by the following claims.

What is claimed is:

1. A method of determining a processing chamber state, comprising:
placing a workpiece in a process chamber;
generating a plasma in the process chamber in order to process the workpiece;
measuring radiation emitted by the plasma during processing of the workpiece;
generating a current model of chamber conditions based on measurements of the emitted radiation; and
comparing the current model of chamber conditions to an ideal model of chamber conditions to determine whether the current model is within a selected confidence level of the ideal model.

2. A method according to claim 1, further comprising:
generating the ideal model of chamber conditions.

3. A method according to claim 1, wherein:
comparing the current model to the ideal model includes performing a multivariate primary component analysis on the current and ideal models.

4. A method according to claim 1, further comprising:
manufacturing a device using the process chamber when the current model is within a selected confidence level of the ideal model.

5. A method according to claim 1, further comprising:
processing cycling workpieces in the process chamber when the current model is outside a selected confidence level of the ideal model

6. A method according to claim 1, wherein:
measuring radiation emitted by the plasma includes determining a relative intensity of an emission spectrum of the plasma as a function of wavelength.

7. A method according to claim 6, wherein:
measuring radiation includes capturing optical radiation emitted by a plasma in the processing chamber during processing of the workpiece.

8. A method according to claim 1, further comprising:
setting a confidence level for the comparison of the current and ideal models.

9. A method according to claim 1, further comprising:
performing a wet etch on the process chamber before placing the workpiece in the process chamber.

10. A method according to claim 1, further comprising:
flowing a process gas comprising a plurality of precursor gases suitable for forming the plasma into the process chamber.

11. A method according to claim 1, further comprising:
processing the workpiece in the process chamber, wherein the processing includes one of depositing a material on, and etching material from, the workpiece.

12. A workpiece processing system, comprising:
a housing defining a process chamber, the process chamber including a workpiece holder for supporting a workpiece in the process chamber and a window for viewing the workpiece during processing of the workpiece in the process chamber;
a plasma generating system operatively coupled to the process chamber and configured to generate a plasma in the process chamber in order to process the workpiece;
an analytical tool positioned outside the process chamber and relative to the window whereby the analytical tool is operable to receive radiation emitted by the plasma during processing of the workpiece, the analytical tool being further operable to measure radiation emitted from the plasma during processing of the workpiece and generate spectral data in response thereto; and
a processing device operable to receive the spectral data and generate a current model of chamber conditions based on the spectral data, the processing device further operable to compare the current model of chamber conditions to an ideal model of chamber conditions in order to determine whether the current and ideal models match to within a selected confidence level of the ideal model.

13. A system according to claim 12, wherein:
the analytical tool is operable to measure the relative intensity of an emission spectrum of the plasma as a function of wavelength.

14. A system according to claim 12, wherein:
the analytical tool is an optical emission spectrograph (OES).

15. A system according to claim 1, wherein:
the processing device is further operable to generate the ideal model of chamber conditions.

15. A system according to claim 11, wherein:
the processing device is operable to compare the current model to the ideal model by performing a multivariate primary component analysis on the current and ideal models.

16. A system according to claim 11, wherein:
the processing device is operable to determine whether to manufacture a device using the process chamber depending upon whether the current model is within a selected confidence level of the ideal model.

17. A system according to claim 11, wherein:
the processing device is operable to determine to process at least one cycling workpiece in the process chamber when the current model is outside a selected confidence level of the ideal model

18. A system according to claim 11, further comprising:
a controller operable to allow a user to select a confidence level for the comparison of the current and ideal models.

19. A system according to claim 11, further comprising:
a gas-delivery system configured to introduce gases into the process chamber; and
a pressure-control system for maintaining a selected pressure within the process chamber during processing.

20. A system according to claim 18, wherein:
the controller is further operable to control the processing of the workpiece in the process chamber.

21. A system according to claim 11, wherein the workpiece includes a silicon wafer.

22. A computer program product embedded in a computer-readable storage medium, comprising:
computer program code for receiving spectral data corresponding to the optical emission of a plasma during processing of a workpiece; and
computer program code for analyzing at least a portion of the spectral data to generate a current model of chamber conditions based on the analyzed spectral data; and
computer program code for comparing the current model of spectral data with an ideal model of spectral data to determine whether the current and ideal models match within a selected confidence level.

23. A computer program product according to claim 22, further comprising:
computer program code for generating the ideal model of chamber conditions.

24. A computer program product according to claim 22, wherein:
computer program code for comparing the current and ideal models includes computer code for performing multivariate primary component analysis on the current and ideal models.

25. A computer program produce according to claim 22, further comprising:
computer program code for indicating to an operator whether the current and ideal models match within a selected confidence level.
